(19) United States
(12) Patent Application Publication
(10) Pub. No.: US 2002/0081817 A1
(43) Pub. Date: Jun. 27, 2002

(54) Void reduction and increased throughput in trench fill processes

(76) Inventors: Jayendra Bhakta, Sunnyvale, CA (US); Robert B. Ogle, San Jose, CA (US)

Correspondence Address: David A. Blumenthal, Foley & Lardner, Suite 3500, 2029 Century Park East, Los Angeles, CA, 90067-3021, US

(21) Appl. No.: 09/746,838

(22) Filed: Dec. 22, 2000

(51) Int. Cl. H01L 21/76

(52) U.S. Cl. 438/424

(57) ABSTRACT

A process for fabricating a trench isolation involves depositing a trench isolation filler material in two layers. The first layer is deposited in the trench at a slow deposition rate. By utilizing the slow deposition rate, the trench is filled without forming significant voids. Next, a second layer is formed by depositing filler material in the trench at a high deposition rate. Use of the high deposition rate provides a higher overall process throughput.

### FIELD OF THE INVENTION

The present invention relates generally to an integrated circuit (“IC”). More specifically, this invention relates to fabrication of an integrated circuit to provide an improved trench fill yield and throughput.

### BACKGROUND OF THE INVENTION

The present invention applies particularly to the fabrication of logic devices and integrated circuits. Some examples of integrated circuits include an EPROM, an EEPROM, a flash memory device, and a complementary metal oxide silicon (“CMOS”) type device. An exemplary device may comprise a field-effect transistor (“FET”) containing a metal gate over thermal oxide over silicon (“MOSFET”), as well as other ultra-large-scale integrated-circuit (“ULSI”) systems.

Integrated circuits are utilized in a wide variety of commercial and military electronic devices, including, e.g., hand held telephones, radios and digital cameras. The market for these electronic devices continues to demand devices with a lower voltage, a lower power consumption and a decreased chip size. Also, the demand for greater functionality is driving the “design rule” lower, for example, into the sub-half micron range. The sub-half micron range may comprise, e.g., decreasing from a 0.35-0.25 micron technology to a 0.18 micron or a 0.15 micron technology, or even lower.

The fabrication of many types of integrated circuit devices involves forming trench isolations for reducing interference between adjacent devices. In general, a trench isolation is formed by forming a trench in a substrate, depositing a layer of insulating material over the substrate, and removing the insulating material to the level of the substrate so that only the material deposited in the trench remains. Where polishing is used to remove the insulating material, it is important to carefully control the polishing step so that polishing is applied evenly across the wafer. Conventional processes address this problem by depositing the insulating material to a depth that overfills the trench. The typical overfill is approximately 40% of the total depth of the trench at the time of the deposition, including any intermediate layers. The overfill smooths the contours in the surface of the fill material corresponding to the corners of the trenches, which improves the uniformity of subsequent polishing.

FIG. 1 shows a trench fill structure formed by a first conventional fabrication process using high growth rate processing parameters. In FIG. 1, a trench 170 for use as a trench isolation is formed in a substrate 120 utilizing conventional techniques. In a typical conventional application, the trench 170 is formed by removal of substrate material so that the trench bottom surface is approximately 2000-5000 Angstroms from the substrate top surface. A thermal oxide layer 160 lines the trench. Deposited over the trench 170 and the substrate 120 is a trench filler material 130. The filler material is formed using a TetraEthylOrthoSilicate (“Ozone TEOS”) technique as is conventionally utilized in the fabrication of circuit devices.

The material deposited in the trench grows upward from the bottom surface and outward from the sidewalls. Because of the high rate of deposition, the rate of outward growth at the top portions of the sidewalls exceeds the rate of growth from the middle portions, causing the top portions to meet and close off the trench before it is filled. This produces a void 180 in the filler material. The void is detrimental to the isolation characteristics of the trench.

FIG. 2 illustrates a structure formed in a second conventional technique. In this technique, filler material 130 is deposited at a slower rate than in the process of FIG. 1. This achieves precise filling of the shallow trench isolation region 170 without producing the void illustrated in FIG. 1. However, formation of the slow deposition rate material requires substantial additional processing time. Further, the slow deposition rate material is significantly more difficult to polish than the high deposition rate material. Thus the additional time required for processing low deposition rate material can make the use of this material cost prohibitive.

### SUMMARY OF THE INVENTION

Embodiments of the invention form trench isolations in a manner that provides improved throughput relative to conventional techniques. The improvement is achieved by utilizing a variable deposition rate process that combines the superior fill properties of slow rate deposition with the superior throughput of high rate deposition.

In an exemplary embodiment, a trench isolation filler material is deposited in two layers. The first layer is deposited over the substrate and trench at a slow deposition rate to fill the trench with filler material. By utilizing the slow deposition rate, the trench is filled without forming voids . Next, a second layer is formed by depositing filler material to a second depth over the substrate at a high deposition rate to provide overfill. The high rate of the second deposition improves process throughput during formation, and the higher polishing rate of the second layer further improves throughput during polishing. Other arrangements and modifications will be understood by examining the detailed description and the appended claims with reference to the drawings.

### DESCRIPTION OF THE DRAWINGS

Embodiments of the present invention are described in detail herein with reference to the drawings in which:

FIG. 1 illustrates a cross-sectional representation of a first conventional shallow trench isolation structure;

FIG. 2 illustrates a cross-sectional representation of a second conventional shallow trench isolation structure; and

FIGS. 3a, 3b, 3c 3d, 3e, 3f, 3g, 3h, 3i, 3j, 3k and 3l illustrate structures formed during a process in accordance with exemplary embodiments of the invention.

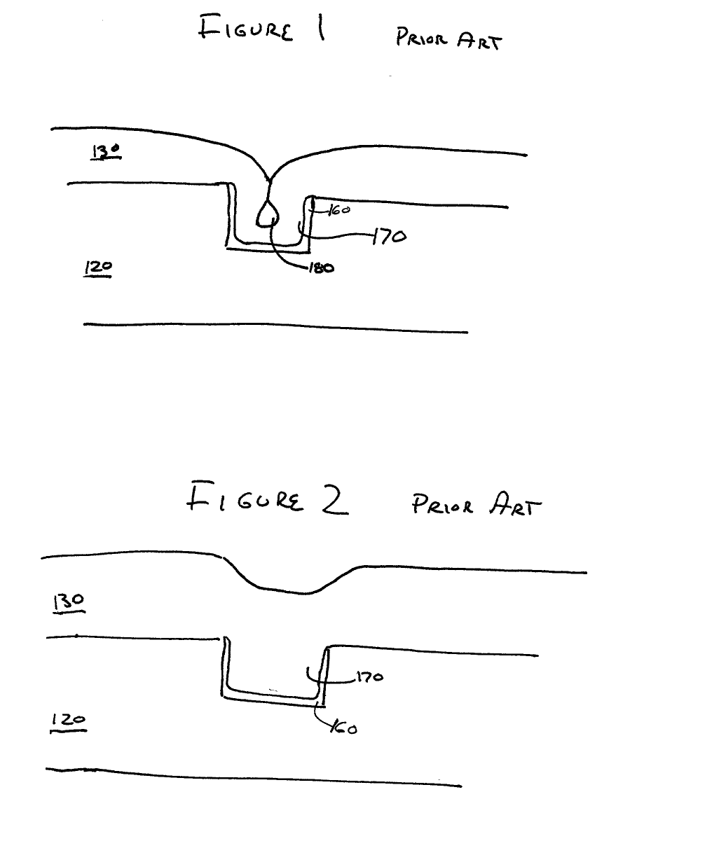

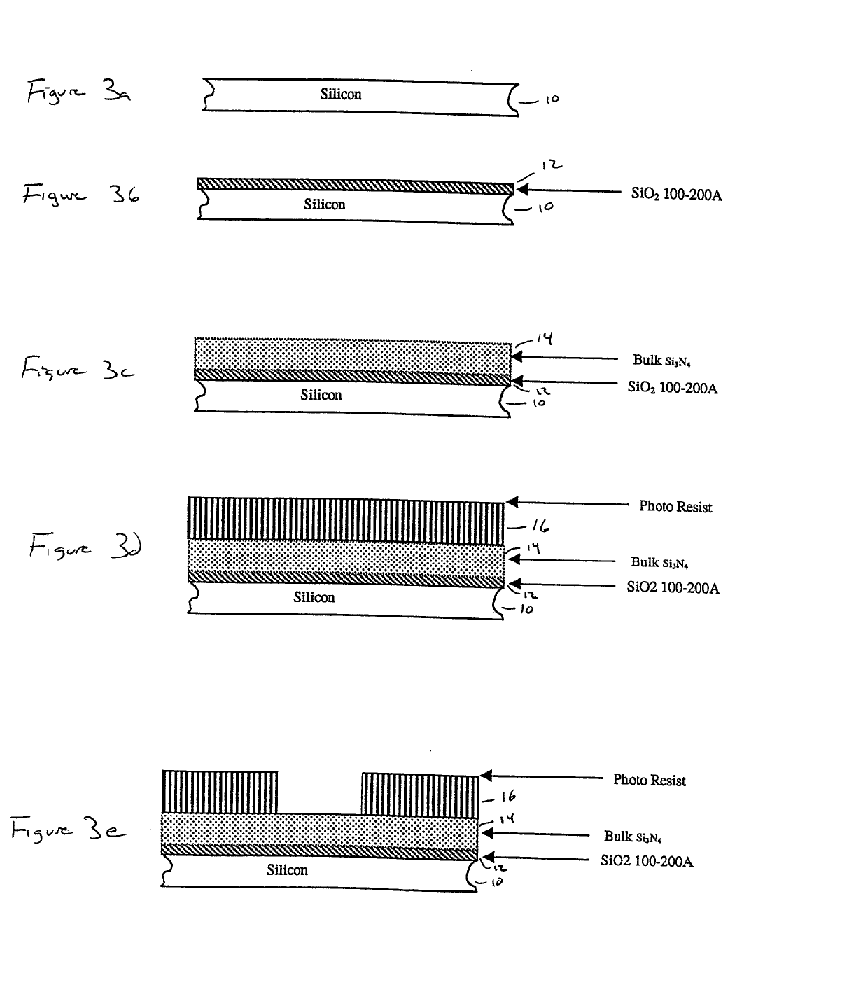

The accompanying drawings, wherein like numerals denote like elements, are incorporated into and constitute a part of the specification, and illustrate presently preferred exemplary embodiments of the invention. However, it is understood that the drawings are for the purpose of illustration only, and are not intended as a definition of the limits of the invention. Thus, the drawings, together with the general description given above, and the detailed description of the preferred embodiments given below, together with the appended claims, serve to explain the principles of the invention.

### DETAILED DESCRIPTION OF PREFERRED EMBODIMENTS

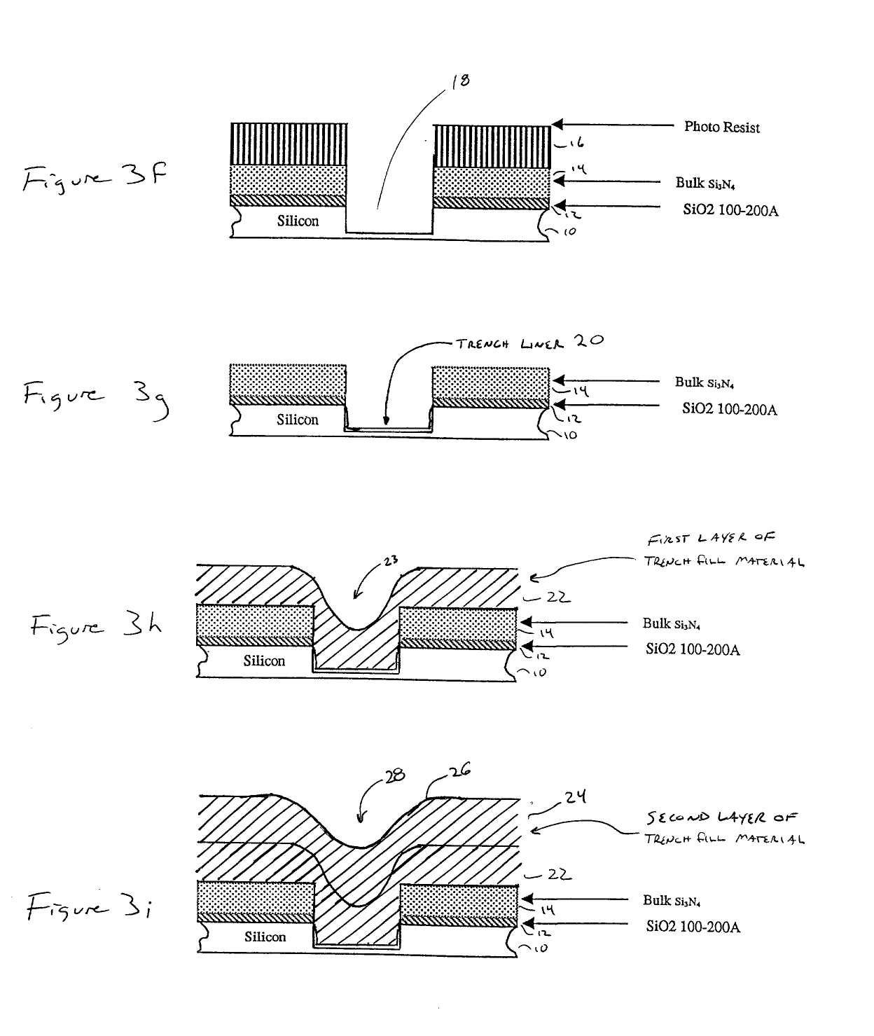

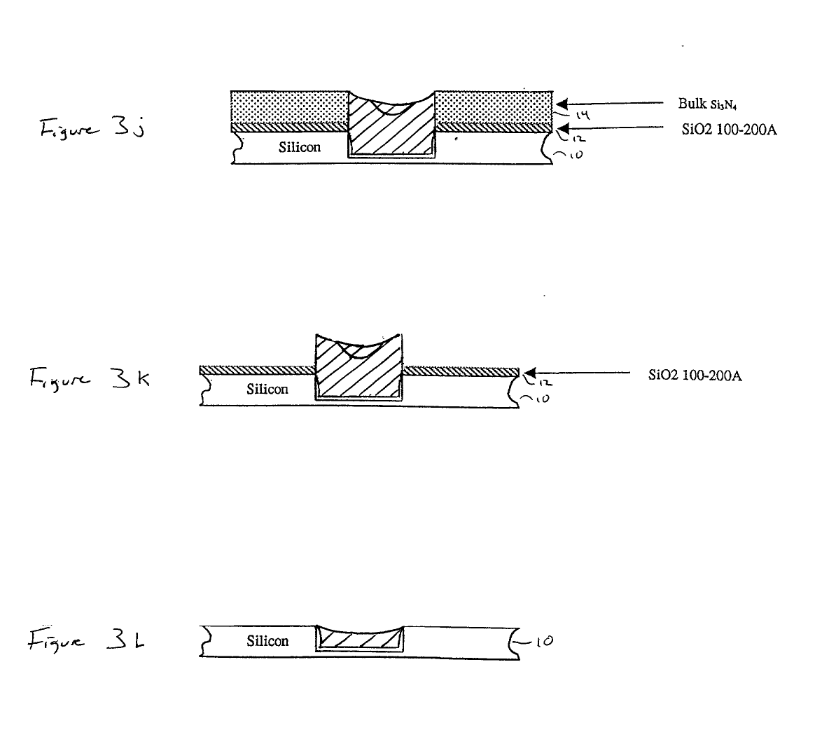

FIGS. 3a-3k illustrate intermediate structures and FIG. 3l illustrates a final structure formed through an exemplary fabrication process in accordance with the invention. It will be understood by one skilled in the art that various conventional aspects of the process are not illustrated in FIGS. 3a-3l in order to simplify the illustrations. Also, the various parameters associated with the illustrated process are exemplary only and those having ordinary skill in the art will be capable of formulating alternative parameters in accordance with other applications of the invention.

FIG. 3a shows a substrate 10 in which a trench isolation is to be formed. While in this example the substrate 10 is composed of silicon, in the context of the invention, the term “substrate” refers to a structure in which a trench is formed. Alternative substrate materials may include doped silicon, gallium arsenide (GaAs), gallium arsenide phosphide (GaAsP), germanium, or silicon germanium (SiGe). A substrate may also include any underlying or overlying materials that may be utilized, or upon which a device, a circuit, or an epitaxial layer may be formed. A substrate may include, for example, a tunnel or a gate oxide layer, or more generally any SiO₂ or Nitride, e.g., Si₃N₄, layer in addition to a silicon layer, as in the present invention.

In FIG. 3b, a silicon oxide pad 12 having a thickness of 100-200 Angstroms is formed on the silicon layer. In FIG. 3c, a bulk silicon nitride layer 14 having a thickness of 1200-1600 Angstroms if formed on the silicon oxide pad 12. The silicon nitride layer 14 serves as a polish stop, described further below, and the silicon oxide layer 12 serves as a thermal stress relief layer to relieve stress that can arise during processing as a result of differences in the thermal expansion coefficients of the nitride layer 14 and the substrate 10.

In FIG. 3d, a layer of photoresist 16 is formed over the silicon nitride layer 14, and in FIG. 3e the photoresist 16 has been patterned to form a mask that exposes an area in which a trench will be etched. In FIG. 3f, a trench 18 has been etched down into the silicon substrate 10. In FIG. 3g, the photoresist has been removed, and a trench liner layer 20 of silicon oxide has been formed by thermal oxidation.

In FIG. 3h, a first layer 22 of an insulating trench fill material is deposited in the trench 18 and over the silicon nitride layer 14 at a slow rate of deposition. The slow rate of deposition allows the side walls to grow in a uniform manner that avoids producing a void in the deposited material. The resulting trench fill has a depression 23 centered over the trench, as shown in FIG. 3h. The trench fill material of the first layer 22 is deposited at least until the side walls of the trench meet in the center of the trench. This effectively requires the first layer 22 to be deposited to a depth of at least one-half the effective width of the trench 18 prior to deposition of the first layer 22. It is preferable however to deposit the first layer 22 to a depth slightly greater than one-half the width of the trench. In alternative embodiments of the invention, the first layer 22 may substantially fill the trench 18 and even overfill the trench 18.

The trench fill material of the first layer 22 may be an oxide deposited by Plasma-Enhanced Chemical Vapor Deposition (“PECVD”). The PECVD oxide may be achieved, e.g., by a TetraEthylOrthoSilicate (“TEOS”) tehnique or by a High Density Plasma (“HDP”) oxide technique. The HDP oxide technique, which does not require annealing immediately after the deposition, may be utilized in a preferred arrangement of the present invention, as compared to the TEOS technique, which does require annealing.

In the preferred embodiment, a 20-25 Angstroms per minute deposition rate at a temperature of approximately 600-650° C. and a pressure of 300-600 mTorr is used. A flow rate of TEOS preferably is approximately 80-200 sccm, with an oxygen supply flow rate of approximately 2-50 sccm. The depth of deposited material may be controlled based on the deposition rate and the elapsed time of deposition.

In FIG. 3i a second layer 24 of trench fill material is deposited at a deposition rate that is higher than the rate of the first layer. The material is deposited to a level that provides overfill of the trench 18. The second layer 24 has a surface 26 that includes a depression 28 centered over the trench. The corners of the depression are smoother than those in the first layer 22. While the trench fill materials of the first and second layers are essentially the same in material composition, the material of the second layer 24 has a higher polish rate that speeds processing as described below. Further, by depositing the second layer 24 of the trench fill material at a higher deposition rate than the first layer, a higher processing throughput is realized.

In the preferred embodiment the second layer 24 of trench fill material is deposited at a rate of approximately 50-70 Angstroms per minute at a temperature in the range of 630-700° C., and preferably at a deposition rate of 60-70 Angstroms per minute and a temperature of approximately 630-700° C. Deposition gas pressure is preferably maintained at approximately 600-3,000 mTorr. In this preferred embodiment, TEOS gas may be supplied at a flow rate of approximately 80-200 sccm with an oxygen flow rate of approximately 2-50 sccm.

In FIG. 3j, the layers 22 and 24 of trench fill material have been removed by planarization, for example, by chemical mechanical polishing, to the level of the surface of the nitride layer 14. Since the second layer 24 of the trench fill material is deposited at a high deposition rate, the polishing of the top surface is completed at an increased rate because the second layer of trench fill material is softer and requires less polishing time than the first layer 22 as a result of its higher deposition rate. The underlying nitride layer 14 is significantly harder than the first and second trench fill material layers 22, 24 and acts as a polish stop. Although the trench fill material is subjected to a “dishing” effect, which is exhibited as a depression in the trench fill material relative to the nitride, it is still preferable to employ the nitride as a polish stop so that there is an over-all uniformity of the depth of trench fill material across multiple trenches after polishing is completed. The extent of the dishing effect is limited by providing the overfill of trench material described above so that the corners of depressions above trenches have relatively smooth contours.

In FIG. 3k the nitride layer 14 has been removed by a wet clean process such as a hot phosphoric acid wash. The phosphoric acid has an etch ratio of approximately 30:1 with respect to the trench oxide.

In FIG. 3l, the oxide layer 12 has been removed using a wet clean process such as a hydrofluoric acid wash that has a high etch ratio with respect to the silicon substrate. The wash removes the material of the oxide layer 12 and the trench fill layers 22, 24 to the level of the silicon substrate. The resulting fill material in the trench retains the dishing contour that was produced by polishing in FIG. 3j.

In alternate embodiments, the first and second portions of the trench isolation material may be varied in thickness, depending upon the design requirements and the increase in throughput desired for the circuit device. For example, the throughput may be decreased by increasing the relative thickness of the second trench fill material layer 24 or may be increased as desired by reducing the relative thickness 24 of the second trench fill material layer and/or increasing the relative thickness of the first trench fill material layer.

It will be appreciated by those skilled in the art that further processing steps in the formation of a circuit device, e.g., formation of active regions in the silicon substrate, may be practiced in conjunction with the structure and process of the present invention.

In alternative embodiments, it may be preferred to anneal the TEOS material before further processing in order to decrease the etch rate of the TEOS materials to provide resistance during cleaning steps. Annealing TEOS in an O₂ atmosphere further creates a thin layer of thermal oxide under the TEOS which creates a rounded edge and improves the quality of the oxide formed through later fabrication. The use of the anneal presents a tradeoff between the improvements provided by the anneal and the increased processing time resulting from the lowered TEOS etch rates. However, processing time improvements realized through the higher rate of deposition as described above are retained.

The invention has been described in reference to particular embodiments as set forth above. However, only preferred embodiments of the present invention are shown and described in the present disclosure. It is to be understood that the present invention is capable of use in various other combinations and environments, and is capable of changes or modifications within the scope of the inventive concept as expressed herein. Also, many modifications and alternatives will become apparent to one of skill in the art without departing from the principles of the invention as defined by the appended claims.

What is claimed is:

1. A method of fabricating a trench isolation, comprising:
forming a trench in a substrate;
depositing a first layer of trench fill material over the trench at a first deposition rate;
depositing a second layer of trench fill material over the trench at a second deposition rate that is higher than the first deposition rate; and
removing material of the first and second layers to the level of the substrate.

2. The method claimed in claim 1, wherein depositing the first layer of trench fill material is performed at a rate sufficient to prevent the formation of voids in the first layer within the trench.

3. The method claimed in claim 1, wherein the first layer of trench fill material is deposited to a depth that is at least one half the width of the trench.

4. The method claimed in claim 1, wherein depositing the first layer is performed until trench fill material surfaces growing outward from respective side walls of the trench meet.

5. The method claimed in claim 1, wherein the material of the second layer has a higher polishing rate than the material of the first layer.

6. A method as claimed in claim 1, wherein the first layer is a silicon oxide layer deposited at a rate of approximately 20-25 Angstroms per minute, and wherein the second layer is a silicon oxide layer deposited at a rate of approximately 50-70 Angstroms per minute.

7. A method as claimed in claim 1, wherein the first layer is a silicon oxide layer deposited at a temperature in the range of approximately 600-650 C., and wherein the second layer is a silicon oxide layer deposited at a temperature in the range of approximately 630-700° C.

8. A method as claimed in claim 1, wherein the first layer is a silicon oxide layer deposited at a pressure of approximately 300-600 mTorr using a TEOS gas at a flow rate of approximately 80-200 SCCM and an oxygen supply flow rate of approximately 2-50 SCCM, and wherein the second layer is a silicon oxide layer deposited at a pressure of approximately 600-3000 mTorr using a TEOS gas at a flow rate of approximately 80-200 SCCM and an oxygen supply flow rate of approximately 2-50 SCCM.

9. A method as claimed in claim 1, wherein forming the trench in the substrate comprises:
depositing a polish stop layer over the substrate;
patterning a photoresist mask on the polish stop layer to define a trench area; and
etching through the polish stop layer to form a trench in the substrate, and
wherein the first and second trench fill material layers are deposited over the polish stop layer.

10. A method as claimed in claim 9,
wherein depositing the polish stop layer is preceded by depositing a thermal stress relief layer on the substrate, and
wherein depositing the polish stop layer over the substrate comprises depositing the polish stop layer on the thermal stress relief layer.

11. A method as claimed in claim 10,
wherein the substrate is a silicon substrate,
wherein the thermal stress relief layer is a silicon oxide layer, and
wherein the polish stop layer is a silicon nitride layer.

12. The method as claimed in claim 10, further comprising:
removing the trench fill material to the level of the polish stop layer;
removing the polish stop layer; and
removing the thermal stress layer.

13. The method as claimed in claim 12,
wherein the first and second trench fill material layers and the thermal stress layer are silicon oxide layers, and
wherein removing the thermal stress layer also removes material of at least one of the first and second trench fill layers.

14. The method as claimed in claim 9, further comprising:
removing the trench fill material to the level of the polish stop layer; and
removing the polish stop layer.

15. The method claimed in claim 9, wherein forming a trench isolation region further comprises forming a thermal oxide in the trench.

16. A method of avoiding void formation in a trench isolation fabrication process comprising:
(a) at least partially filling a trench with a first layer of trench fill material at a first rate that is sufficiently slow to permit trench fill material growing outward from respective side walls of the trench to meet without void formation therebetween; and
(b) filling any remaining portion of the trench, and covering a region adjacent a top of the trench, with a second layer of a trench fill material at a second rate higher than said first rate.

17. The method claimed in claim 16, further comprising:
(c) removing at least a portion of the second layer at a first removal rate; and
(d) removing at least a portion of the first layer at a second removal rate that is lower than the first removal rate.

18. The method claimed in claim 16, further comprising:
(c) annealing the material of the first and second layers of trench fill material;
(d) removing at least a portion of the second layer at a first removal rate; and
(e) removing at least a portion of the first layer at a second removal rate that is lower than the first removal rate.
